(19) United States
(12) Patent Application Publication
(10) Pub. No.: US 2026/0045441 A1
(43) Pub. Date: Feb. 12, 2026

(54) CHARGED PARTICLE LENS

(71) Applicant: FEI Company, Hillsboro, OR (US)

(72) Inventors: Radovan VAŠINA, Brno (CZ); Bohuslav SED’A, Blansko (CZ); Jan STOPKA, Brno (CZ); Juraj RUSNACKO, Lucivná (SK); Chris SEARS, Happy Valley, OR (US)

(73) Assignee: FEI Company, Hillsboro, OR (US)

(21) Appl. No.: 19/291,480

(22) Filed: Aug. 5, 2025

Related U.S. Application Data
(60) Provisional application No. 63/680,028, filed on Aug. 6, 2024.

(51) Int. Cl. H01J 37/141; H01J 37/12; H01J 37/28

(52) U.S. Cl. CPC H01J 37/1413; H01J 37/28; H01J 37/12; H01J 2237/1035

(57) ABSTRACT

A charged particle lens for focusing a beam of charged particles towards a sample mounted at a sample position. The charged particle lens comprises a first pole piece, a second pole piece, a lens coil and at least one voltage supply. The second pole piece is electrically insulated from the first pole piece and has a central aperture, wherein the second pole piece is arranged to be aligned with the first pole piece, which also has a central aperture, such that a central axis of the charged particle lens extends through the central aperture of the first pole piece and the second pole piece. The lens coil is arranged to generate a magnetic field at the first and second pole pieces, and the at least one voltage supply is arranged to apply a potential difference between the second pole piece and the sample to generate an electric field.

### CROSS-REFERENCE TO RELATED APPLICATION

This application claims the benefit of U.S. Provisional Ser. No. 63/680,028, filed Aug. 6, 2024, and is incorporated by reference herein.

### FIELD OF THE DISCLOSURE

The disclosure relates to a charged particle lens for focusing a beam of charged particles towards a sample mounted at a sample position. The charged particle lens may be used within a scanning electron microscope, more specifically arranged at an end of a booster tube of a scanning electron microscope, in order to generate an electromagnetic immersion field. There is also described a scanning electron microscope comprising the charged particle lens, and a method of focusing a beam of charged particles towards a sample mounted at a sample position.

### BACKGROUND TO THE DISCLOSURE

A scanning electron microscope, SEM, is a type of microscope that produces images by transmitting a beam of charged particles (such as electrons) on to the surface of a sample. The charged particles interact with the surface of the sample, and information about the sample can be obtained based on the detection of charged particles reflected and/or emitted from the sample surface. The SEM may provide information and imaging of the topology of the sample surface, as well as information on the sample composition. SEM imaging allows for production of particularly high-resolution images, in some cases better than 1 nm resolution.

Modern SEMs use a booster tube that accelerates electrons during their passage through an SEM column, thus minimising Coulomb interactions, effects of environmental stray fields and charging effects. The optical properties of an SEM with a booster tube (including the ability to focus, magnify and demagnify the charged particle beam) are mainly determined by a final optical element (for instance, a lens) situated at the end of the booster tube, and through which any charged particles must pass before being incident at a sample. The final optical element may be an objective lens to focus the beam onto the sample. The objective lens may for example be a simple magnetic lens, an immersion lens in which the sample is immersed in a magnetic field, or more recently compound lenses have been developed comprising both a magnetic immersion lens and an electrostatic lens. Especially where the SEM makes use of electrons at low energy, compound lenses have been found to provide improved image resolution due to the acceleration electrostatic field in parallel with the immersion magnetic field, which minimises optical aberrations by providing a maximum of the electromagnetic field as close as possible to the sample.

The current state-of-the-art SEMs usually utilize a booster tube that can provide charged particles having low landing energies (e.g. having energies of around 50 eV). The booster tube is an optically continuous tube held at a constant high voltage potential (e.g. from +5 to +10 kV). The end of the booster tube inevitably creates an electrostatic lens. This electrostatic lens affects the electron beam as a convergent lens that changes the electron energy at the same time. The position of the electrostatic lens is important for the optical properties of the SEM. The general teaching in the art is that better optical properties are achieved the closer the electrostatic lens is positioned to the focus point of the charged particle beam (e.g. optical properties are improved the closer the proximity of the electrostatic lens to the sample).

A compound lens will further comprise a magnetic lens. In prior art compound lenses, the electrostatic and magnetic lenses are arranged in series, each providing an effect to the charged particle beam. Final magnetic lenses at SEMs are generally of better quality than electrostatic ones, and so it is typical to design the compound electrostatic magnetic lens in such way that focusing due to magnetic refraction is the principal effect. The ultimate magnetic lens is the magnetic immersion lens, often called a single pole magnetic lens. A schematic diagram of a known compound lens is shown at FIG. 1, illustrating focusing of a beam of charged particles 10 on to a sample surface 12 by the electrostatic lens 14 and magnetic lens 16. Again, it is recognised that the closer the magnetic lens is located to the plane of focus, then the better the overall optical properties of the final lens. Examples of known compound lenses for demonstrating focusing as shown in FIG. 1 can be seen in European Patent Publications No. EP 2706554 and EP 2833390.

In view of the above, it is desired to provide a charged particle lens with improved performance compared to the prior art.

### SUMMARY

In a first aspect, there is described a charged particle lens for focusing a beam of charged particles towards a sample mounted at a sample position, the charged particle lens comprising:
a first pole piece, having a central aperture;
a second pole piece, being electrically insulated from the first pole piece and having a central aperture, wherein the second pole piece is arranged to be aligned with the first pole piece such that a central axis of the charged particle lens extends through the central aperture of the first pole piece and the second pole piece, the central apertures of the first pole piece and the second pole piece for passing the beam of charged particles towards the sample;
a lens coil arranged to generate a magnetic field at the first pole piece and at the second pole piece; and
at least one voltage supply, arranged to apply a potential difference between the second pole piece and the sample mounted at the sample position to generate an electric field;
the generated magnetic field and generated electric field for focusing a beam of charged particles passing through the central apertures of the first and second pole piece.

In a second aspect there is described a scanning electron microscope, SEM, comprising the charged particle lens.

In a third aspect there is described a method of focusing a beam of charged particles towards a sample mounted at a sample position, comprising:
providing a charged particle lens, comprising:
   a first pole piece, having a central aperture;
   a second pole piece, being electrically insulated from the first pole piece and having a central aperture, wherein the second pole piece is arranged to be aligned with the first pole piece such that a central axis of the charged particle lens extends through the central aperture of the first pole piece and the second pole piece, the central apertures of the first pole piece and the second pole piece for passing the beam of charged particles towards the sample;
   a lens coil arranged to generate a magnetic field at the first pole piece and at the second pole piece; and
   at least one voltage supply, arranged to apply a potential difference between the second pole piece and the sample mounted at the sample position to generate an electric field;
wherein the method further comprises:
generating the magnetic field and the electric field whilst passing the beam of charged particles through the central aperture of the first pole piece and the second pole piece towards the sample, the generated magnetic field and generated electric field for focusing the beam of charged particles towards the sample.

### BRIEF DESCRIPTION OF THE FIGURES

The disclosure may be put into practice in various ways, some of which will now be described by way of example only and with reference to the accompanying drawings in which:

FIG. 1 shows a schematic representation of a compound lens according to the prior art;

FIG. 2 shows a cross-sectional view of an example of the disclosed charged particle lens;

FIG. 3 shows a cross-sectional view of the charged particle lens of a SEM;

FIG. 4 shows a schematic representation of the charged particle lens of FIG. 3;

FIG. 5 illustrates a plot of the magnetic field generated at a first example configuration of the charged particle lens;

FIG. 6 illustrates a plot of the magnetic field generated at a second example configuration of the charged particle lens; and

FIG. 7 illustrates a cross-section of the charged particle lens, illustrating an example of the insulating element.

It will be understood that like features are labelled using like reference numerals. The figures are not to scale.

### DETAILED DESCRIPTION OF SPECIFIC EXAMPLES

The disclosure considers a charged particle lens (that could also be considered a compound lens, or charged particle compound electrostatic magnetic immersion lens), which may be used within a scanning electron microscope (SEM). In particular, the described charged particle lens comprises a single element providing a magnetic lens and an electrostatic lens. Combining both the electrostatic and magnetic lens of a compound lens within a single physical element removes the requirement for alignment of the focusing fields, and so reduces parasitic aberration resulting from misalignment. The described charged particle lens can provide a number of other benefits, as described below.

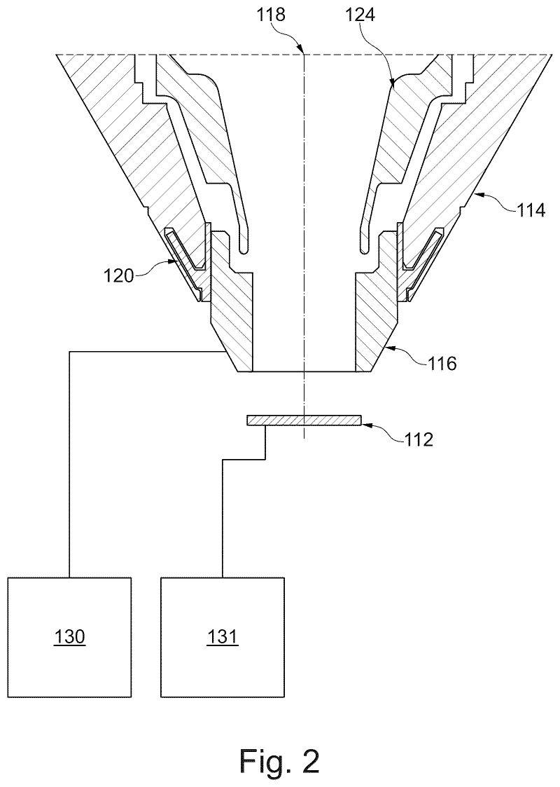

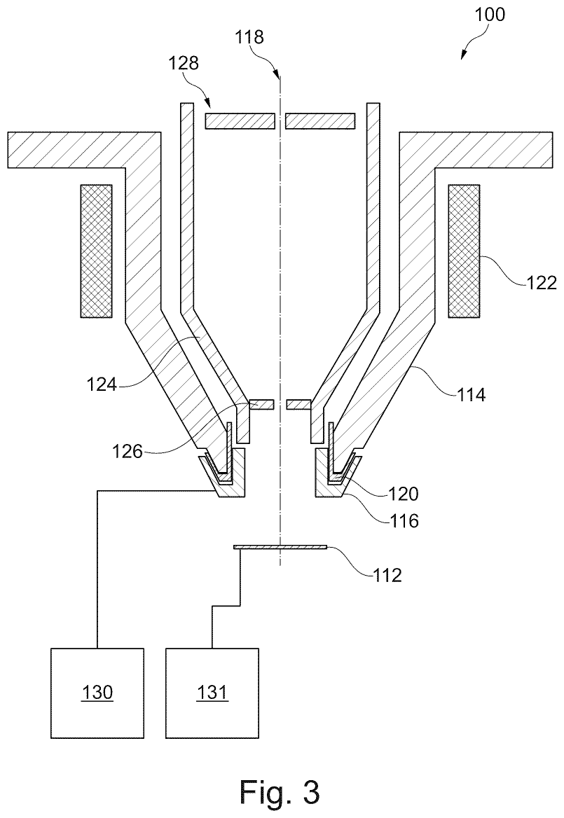

FIG. 2 shows a cross-sectional view of an example charged particle lens according to the present disclosure. FIG. 3 shows a schematic, cross-sectional view of the charged particle lens at a column of an SEM. The charged particle lens comprises a first pole piece 114 and a second pole piece 116. A lens coil 122 (shown in FIG. 3 only) is arranged around the outer surface of the first pole piece 114 so that, when the lens coil 122 is energised, a magnetic field is generated at the first pole piece 114 and the second pole piece 116. The generated magnetic field is an immersion field, having a maximum magnitude located in the sample chamber and close to the sample position at which a sample 112 is mounted when the SEM is in use. The magnetic field acts as a magnetic lens for focusing a charged particle beam passing through the charged particle lens towards the sample 112.

At least one voltage supply is arranged to apply a potential difference between the first pole piece 114 and the second pole piece 116, as well as between the second pole piece 116 and a sample 112 at a sample position. In the specific example of FIG. 2, a first voltage supply 130 is configured to apply a voltage to the second pole piece 116, which is electrically isolated from both the first pole piece 114 and the sample 112. In the example of FIG. 2, the sample position (or sample holder) is also connected to a second voltage supply 131, which can apply a voltage of positive or negative polarity (thereby in turn maintaining the sample 112 at a specific voltage). Appropriate choice of voltages applied at the first and second voltage supply generates a potential difference between the second pole piece and the sample 112 mounted at the sample position. The potential difference in turn generates an electric field, which acts as an electrostatic lens for focusing the charged particle beam passing through the charged particle lens towards the sample 112. As an alternative to the example of FIG. 2, it will be understood that either of the sample position or second pole piece could be connected to ground and earthed, with a voltage applied via a voltage supply to the other element, in order to generate a potential difference between a sample 112 at the sample position and the second pole piece 116.

The first pole piece 114 is an element having an approximately frustoconical shape at its outer surface, as well as a central aperture or bore extending therethrough (resulting in truncation of the tip of the conical shape). A pole piece is a structure composed of material of high magnetic permeability that serves to direct a magnetic field produced by a lens coil 122, and the first pole piece 114 is formed of a material that is both ferromagnetic and electrically conductive.

The second pole piece 116 is an element having an approximately conical or cylindrical shape, with a central aperture or bore extending therethrough. The second pole piece 116 is arranged to at least partially extend from the first pole piece 114 towards the sample position. In particular, the second pole piece 116 is arranged to be aligned with the first pole piece 114 such that a central axis 118 of the charged particle lens extends through the central aperture of the first pole piece 114 and the second pole piece 116. As such, a continuous passage extends through the central aperture of the first pole piece 114 and then the second pole piece 116.

The second pole piece 116 is formed of a material that is both ferromagnetic and electrically conductive. As such, the high magnetic permeability of the material allows the second pole piece 116 to direct a magnetic field, whilst the electrical conductivity allows establishment of an electric field when a voltage is applied.

The second pole piece 116 is spaced apart from, and electrically insulated from, the first pole piece 114. Although in some cases the spacing or separation of the first pole piece 114 and second pole piece 116 alone could provide electrical insulation, in the example of FIG. 2 an insulating element 120 is arranged between the first pole piece 114 and the second pole piece 114. The insulating element 120 provides stable alignment of the first pole piece 114 and second pole piece 116, as well as reliable electrical insulation between the two pole pieces, even with a large potential difference.

FIG. 3 shows the charged particle lens of FIG. 2 (comprising the first pole piece 114, second pole piece 116, and the insulating element 120) within a zoomed out final lens assembly of a SEM. In particular, the charged particle lens is situated at one end of a booster tube 124 of the SEM. The first pole piece 114 surrounds the booster tube 124 of an SEM, and the second pole piece 116 extends from the first pole piece 114 at one end of the booster tube 124. The central axis 118 that extends through the central aperture of both the first pole piece 114 and the second pole piece 116 also aligns with the central axis of the booster tube 124. The insulating element 120 acts to insulate the second pole piece 116 from the booster tube 124, as well as from the first pole piece 114.

The lens coil 122 is arranged around the outer surface of the first pole piece 114 and connected to magnetic circuitry. When energised, the lens coil 122 generates a magnetic field between the first pole piece 114 and second pole piece 116 and a sample 112 mounted at the sample position. The magnetic field is an immersion magnetic field, having a maximum intensity of the magnetic field in the vicinity of the sample 112 (and sample position).

The SEM further comprises a number of charged particle detectors. In the example of FIG. 3, a first detector 126 is a backscattered electron detector housed in the booster tube 124, at an end closest to the second pole piece 116. The backscattered electron detector is arranged inside the bore of the booster tube 124, and itself has an aperture therethrough. The booster tube also houses a second detector 128 being a secondary electron detector, which is arranged in the bore of the booster tube 124, but further from the sample 112 than the backscattered electron detector. The secondary electron detector also has a central aperture, aligned with the central axis 118. The aperture through the backscattered electron detector and the secondary electron detector allows for passing of the charged particle beam generated at and transmitted from a charged particle source through the SEM (source not shown).

Although not shown in FIG. 2 or FIG. 3, it will be understood that one or more controllers are connected to the SEM. Said controllers may control (individually or in conjunction) one or more of: the magnetic circuitry, a motor to move a sample holder and adjust the sample position, the at least one voltage supply 130, 131, and any charged particle detectors (including the backscattered electron detector and the secondary electron detector). The one or more controllers may form part of a computer implemented control system, which may receive data from the detectors and other aspects of the system for further processing. The described one or more controllers may control the at least one voltage supply 130, including initiating a potential difference between the second pole piece 116 and each of the first pole piece 114 and/or a sample 112 mounted at the sample position, as well as controlling the magnitude of that potential difference. In one example, the controller may initiate and regulate the magnitude of a voltage applied to the second pole piece 116, in order to generate the required electric field.

When the SEM is in use, a charged particle beam passes from the source towards the sample 112 in the direction of the central axis 118, so as to pass through the central apertures of the secondary electron detector and the backscattered electron detector, as well as the central apertures of the first pole piece 114 and second pole piece 116. The electrostatic and magnetic fields generated at the charged particles lens act to focus the charged particle beam on to the surface of the sample 112 at the focal plane. Charged particles incident at the sample 112 can then be reflected from the sample surface (and received at the backscattered electron detector 126) or may cause emission of electrons from the sample surface (which may travel back up through the booster tube, to be detected at the secondary electron detector 128). The measurement of charged particles at the charged particle detectors 126, 128 allows for formation of images by the SEM.

More specifically, when the charged particle lens is in use for focusing the charged particle beam, magnetic circuitry (not shown) energises the lens coil 122, which is arranged to generate a magnetic field at the first pole piece 114 and the second pole piece 116. The first and second pole pieces 114, 116 are magnetised as a consequence of comprising a ferromagnetic material. At the same time, a voltage is applied to the second pole piece 116, which generates a potential difference between the second pole piece 116 and the first pole piece 114, as well as between the second pole piece 116 and a sample 112 mounted at the same position. The presence of a potential difference gives rise to an electrostatic field. Each of the magnetic and electrostatic fields give rise to the focusing effect for the charged particle beam passing through the central aperture of the first and second pole piece 114, 116 (and the booster tube 124). Importantly, the magnetic and electrostatic fields are generated by the same components (being the first and second pole pieces 114, 116). This is in contrast to prior art designs for a charged particle lens, which use two separate components to generate the magnetic and electrostatic field, being a magnetic lens and an electrostatic lens respectively.

The inventors have observed a number of benefits resulting from the integration of the magnetic and electrostatic lens in the manner described. In particular, the proposed design avoids issues experienced in the prior art, wherein the magnetic and electrostatic lenses are misaligned. Misalignment can increase aberrations in the compound lens of the prior art, and deteriorate the resolution possible for images at the SEM. Such misalignment cannot be present in the charged particle lens of FIG. 3, as the magnetic and electrostatic lens are unified, being generated at the same element (the second pole piece 116). Any effect caused by slight misalignment between the first and second pole piece is small enough to be insignificant, and can be disregarded. The focusing effect of the compound electrostatic magnetic immersion lens is determined primarily by the pole piece 116. Accordingly, the presently disclosed charged particle lens provides the best possible concentricity of the magnetic and electrostatic elements (e.g. maximising the transversal overlap between the magnetic and electrostatic fields), giving better resolution images at the SEM and avoiding the requirement for an alignment step by the user or manufacturer of the SEM. In practice, the very tip of the second pole piece 116 (providing the magnetic immersion field) is configured such that it can ‘float’ at a high potential. As a consequence, the most important optical element for the electrostatic magnetic lens is unified in one piece of soft ferromagnetic (or ferrimagnetic) material (being the second pole piece 116). There is no possibility for misalignment between the electrostatic and magnetic field, since it is shaped by the same physical element.

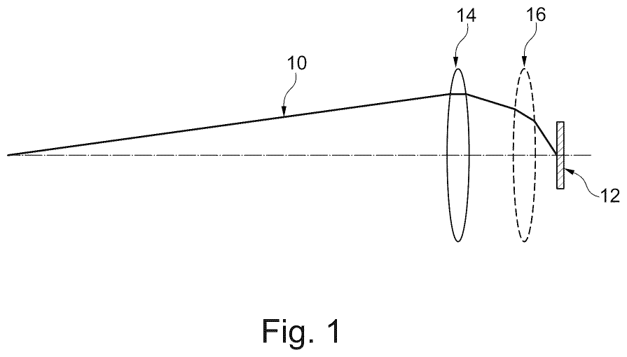

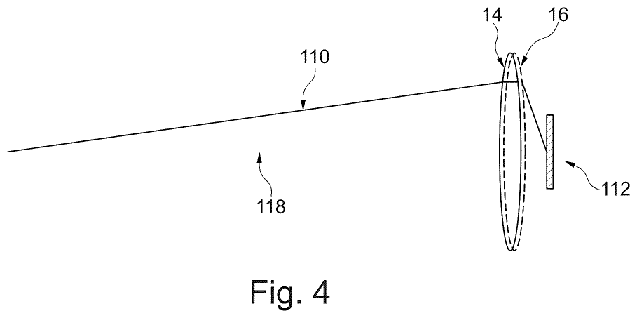

A schematic diagram of the focusing of the charged particle lens of FIGS. 2 and 3 is shown in FIG. 4. Here it can be seen that the effective electrostatic 14 and magnetic 16 lenses are one and the same, and so the respective fields are effectively overlapping, generating an electromagnetic field for focusing the charged particle beam 110 on to a sample 112 at the sample position. This can be compared to a similar diagram at FIG. 1, which shows the two stages of focusing of the charged particle beam that takes place in the prior art compound lens having separate magnetic and electrostatic lenses.

The proposed charged particle lens has demonstrated significant improvements compared to the prior art design. One benefit of the proposed charged particle lens arises from the unification of the magnetic and electrostatic lenses. This allows the compound lens to be arranged closer to the plane of focus (at the sample surface) of the charged particle lens. In turn, the principal plane of the compound charged particle lens is shifted closer to the sample 112, which decreases axial aberrations.

As discussed above, the immersion magnetic field is generated by energising of the lens coil 122, with the magnetic field generated at the first and second pole piece 114, 116. As noted, a separation or spacing is arranged between the first and second pole piece 114, 116, to provide electrical insulation between the two elements. The separation may be achieved by insertion of an insulating element 120 (or spacer) made of electrically insulating material between the two pole pieces 114, 116. A consequence of the spacing between the pole pieces 114, 116 (and the resulting much-reduced magnetic permeability at that point) is a discontinuity or break in the magnetic circuit, which results in a local peak or local maximum being generated in the magnetic field and aligned with the discontinuity. This local peak or maximum is sometimes considered a parasitic magnetic lens, and can itself have an effect on the beam of charged particles.

Preferably, the charged particle lens is configured so as to minimise the effect of said parasitic magnetic lens. In particular, the effect is minimised by designing the arrangement of the first and second pole pieces 114, 116 so as to maximise the overlap of the (unintentional) peak in magnetic field having a smaller, local maximum and caused by the discontinuity in the magnetic circuit with the (intentional) peak in magnetic field generated close to the sample mounted at the sample position and having the global maximum magnitude in the magnetic field. The peak having the global maximum magnitude provides the desired immersion magnetic field. Maximising the overlap is achieved by configuring the second pole piece 116 and first pole piece 114 so that the insulating gap or insulating element 120 (e.g. the discontinuity in the magnetic circuit) is as close as possible to the pole tip of the magnetic circuit. In other words, the gap (and insulating element 120) is arranged as close as possible to the sample 112, whilst still ensuring that the second pole piece 116 extends from the first pole piece 114 to be closer to the sample 112 than the first pole piece 114 (i.e. the portion of the second pole piece 116 between the first pole piece 114 and the sample provides the ‘tip’ of the pole pieces, e.g. the pole tip).

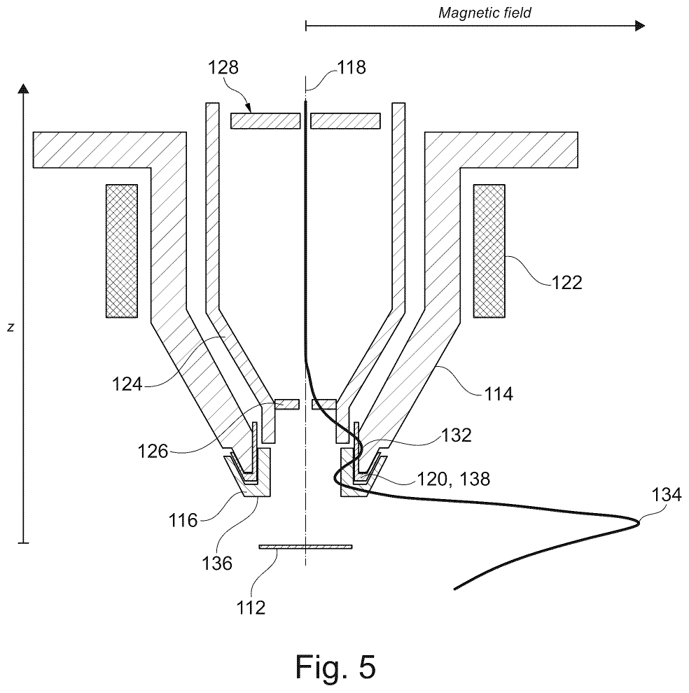

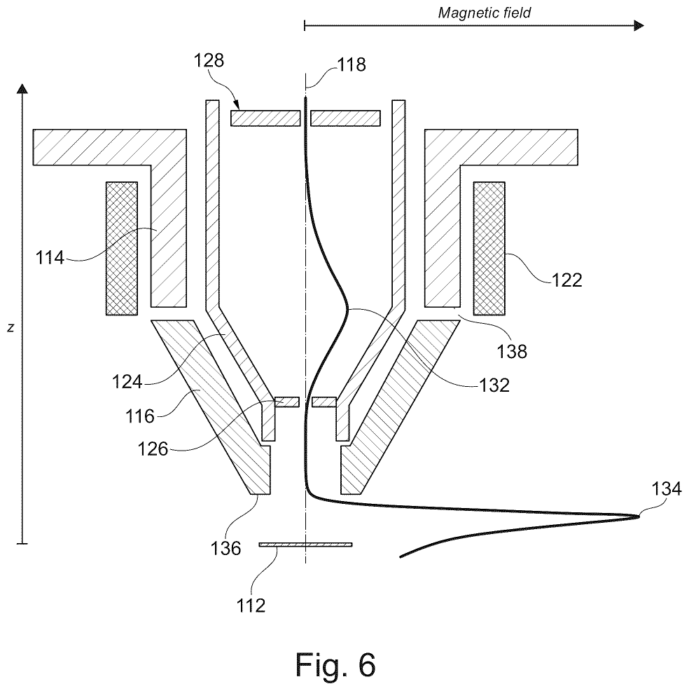

The effect of the discontinuity in the magnetic circuit can be seen by comparison of FIGS. 5 and 6. FIG. 5 shows an example of the charged particle lens according to the elements described above with respect to FIGS. 2 and 3, namely a first pole piece 114 and second pole piece 116 that are electrically insulated from each other. In the example of FIG. 5, the electrical insulation is provided by an insulating element 120 arranged to fill a gap 138 or spacing between the first and the second pole piece 114, 116 and in close proximity to the sample 112.

A plot of the magnitude of the magnetic field in the axial direction is shown in FIG. 5. It can be seen that a local maximum 132 is present in the magnetic field in the region of said gap 138 or separation between the first and the second pole piece (in other words, in the axial position of the discontinuity in the magnetic circuit). In the example of FIG. 5, the local maximum 132 given rise to by the gap 138 between the first pole piece 114 and second pole piece 116 is positioned at a spacing, z, of around 12 mm from the surface of the sample (where the sample is positioned at z=0 mm in the plot of FIG. 5). However, due to the proximity of the gap 138 to the sample, and the location of the gap 138 close to the tip 136 of the second pole piece 116, the peak having the local maximum 132 in the magnetic field (and associated with the presence of the gap) mostly overlaps with the peak having the global maximum 134 in the magnetic field (representing the intentional immersion field). As such, the presence of the gap 138 between the pole pieces 114, 116 (and consequent discontinuity in the magnetic circuit) does not significantly degrade the performance of the charged particle lens.

For comparison, FIG. 6 shows another example of the charged particle lens according to the elements described above with respect to FIGS. 2 and 3 (having a first and second pole piece 114, 116 electrically insulated from each other by a separating gap 138). In the example of FIG. 6, the gap 138 arranged between the first pole piece 114 and the second pole piece 116 is further from the sample 112 than compared to the example of FIG. 5. In the example of FIG. 6, it can be seen that the local maxima given rise to by the gap 138 between the first pole piece 114 and the second pole piece 116 is positioned at a spacing of around 76 mm from the surface of the sample. Once again, the magnitude of the magnetic field in the axial direction is shown, and it can be seen that a local maximum 132 is present in the magnetic field in the axial position of said gap 138. It is noted that the example of FIG. 6 does not include an insulating element 120, but the local maximum 132 is still present because it is caused by the gap in the magnetic circuit of the first and second pole pieces 114, 116.

In the case of FIG. 6, the separation of the local maximum 132 and the overall maximum 134 (providing the immersion field) is such that the local maximum 132 is distinct and does not overlap with the global maximum 134. In the configuration of the example of FIG. 6, the local maximum 132 in magnetic field will act as a parasitic magnetic lens having an effect separate from the immersion field. Said parasitic magnetic lens will degrade the overall performance of the charged particle lens. The performance of the proposed charged particle lens is substantively improved when the gap between the first and second pole piece is positioned as close as possible to the sample.

In view of the above, in a preferred example of the described charged particle lens the gap or spacing 138 between the first pole piece 114 and second pole piece 116 is arranged as close as possible to the pole tip 136 of the charged particle lens. In turn, the separation between the gap or spacing 138 and the sample will also be minimised. As a result, the gap or spacing 138 is arranged so that the local maximum in magnetic field caused by the discontinuity in the magnetic field overlaps as much as possible with the immersion magnetic field peak. In practice, this requires minimising the axial length of the tip portion of the second pole piece 116 (being the portion protruding from the first pole piece towards the sample), and ideally requires minimising the width of the gap or spacing 138 (and so the thickness of the insulating element 120) between the first and the second pole piece 114, 116.

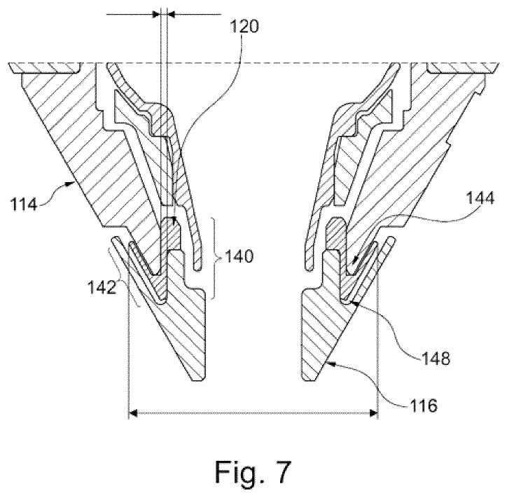

The charged particle lens shown in FIGS. 2 and 3 includes an insulating element 120 having a ‘barbed’ shape. The insulating element 120 is shown in greater detail in FIG. 7. Specifically, the insulating element 120 is a ring arranged to have a ‘v’ shape in a radial cross-section, such that the insulating element 120 has an outermost surface forming a frustoconical shape. In other words, the insulating element 120 comprises an open-ended cylinder portion 140 having a bore extending in the direction of the central axis, and further having a wing 142 extending outwards from one end of the open-ended cylinder portion. In this way, a pointed ‘tip’ 144 of the walls of the first pole piece 114 are arranged in a valley of the ‘v’ shape of the insulating element 120 between the cylinder portion 140 and the wing 142. The insulating element 120 is then arranged within a valley or rim 148 at the wider end of the substantially conical second pole piece 116 which forms the pole tip.

The shape of the insulating element 120 is optimised to provide electrical insulation between the first pole piece 114 and the second pole piece 116 even when a large potential difference is applied between the first and the second pole piece. In particular, the shape and material of the insulating element 120 must withstand large electrical gradients and creepage. In this way the shape of the insulating element 120 shown in FIG. 7 is advantageous, since the surface area between the pole piece at high voltage (typically the second pole piece 116) and the pole piece at ground (typically the first pole piece 114) is maximized, whilst also meeting other constraints as described below. In particular, the shape of the insulating element 120 is based on the following criteria:
to maintain the intensity of the electrostatic field at less than 7000 V/mm;
to maintain the distance between the surfaces of the two pole pieces at different potential so as to provide a spacing of 1 mm for each 1000 V in the potential difference;
to ensure there is no line-of-sight contact between the insulating element 120 and the charged particle beam (the electron primary beam, which would pass towards the sample in the direction of the central axis 118); and
to ensure that the insulating element 120 has no line-of-sight contact with any charged particles emitted or reflected from the sample 112 (the electron signal beam).

The design for the insulating element 120 shown in FIG. 7 is a result of optimising these constraints. Example dimensions (in mm) are shown in FIG. 7, including the thickness of the insulating element 120 required in view of the voltage intended to be applied to the second pole piece 116 (which may be in the range 50-5000 V). However, these dimensions should not be considered to be limiting.

Although examples according to the disclosure have been described with reference to particular types of devices and applications (particularly for use in a scanning electron microscope) and the examples have particular advantages in such a case, as discussed herein, approaches according to the disclosure may be applied to other types of imaging device and/or application. Certain features may be omitted or substituted, for example as indicated herein. Each feature disclosed in this specification, unless stated otherwise, may be replaced by alternative features serving the same, equivalent or similar purpose. Thus, unless stated otherwise, each feature disclosed is one example only of a generic series of equivalent or similar features.

In this detailed description of the various examples and/or embodiments, for the purposes of explanation, numerous specific details are set forth to provide a thorough understanding of the examples and/or embodiments disclosed. One skilled in the art will appreciate, however, that these various examples and/or embodiments may be practiced with or without these specific details. Furthermore, one skilled in the art can readily appreciate that the specific sequences in which methods are presented and performed are illustrative and it is contemplated that the sequences can be varied and still remain within the scope of the various examples and/or embodiments disclosed herein.

As used herein, including in the claims, unless the context indicates otherwise, singular forms of terms are to be construed as including the plural form and vice versa. For instance, unless the context indicates otherwise, a singular reference herein including in the claims, such as “a” or “an” means “one or more”. Throughout the description and claims of this disclosure, the words “comprise”, “including”, “having” and “contain” and variations of the words, for example “comprising” and “comprises” or similar, mean “including but not limited to”, and are not intended to (and do not) exclude other components. Also, the use of “or” is inclusive, such that the phrase “A or B” is true when “A” is true, “B” is true, or both “A” and “B” are true.

The use of any and all examples, or exemplary language (“for instance”, “such as”, “for example” and like language) provided herein, is intended merely to better illustrate the disclosure and does not indicate a limitation on the scope of the disclosure unless otherwise claimed. No language in the specification should be construed as indicating any non-claimed element as essential to the practice of the disclosure.

The terms “first” and “second” may be reversed without changing the scope of the disclosure. That is, an element termed a “first” element or position may instead be termed a “second” element or position and an element termed a “second” element or position may instead be considered a “first”element or position.

Any steps described in this specification may be performed in any order or simultaneously unless stated or the context requires otherwise. Moreover, where a step is described as being performed after another step, this does not preclude intervening steps being performed.

It is also to be understood that, for any given component, example or embodiment described herein, any of the possible candidates or alternatives listed for that component may generally be used individually or in combination with one another, unless implicitly or explicitly understood or stated otherwise. It will be understood that any list of such candidates or alternatives is merely illustrative and not limiting, unless implicitly or explicitly understood or stated otherwise.

The following numbered clauses show further illustrative examples only:
1. A charged particle lens for focusing a beam of charged particles towards a sample mounted at a sample position, the charged particle lens comprising:
   a first pole piece, having a central aperture;
   a second pole piece, being electrically insulated from the first pole piece and having a central aperture, wherein the second pole piece is arranged to be aligned with the first pole piece such that a central axis of the charged particle lens extends through the central aperture of the first pole piece and the second pole piece, the central apertures of the first pole piece and the second pole piece for passing the beam of charged particles towards the sample;
   a lens coil arranged to generate a magnetic field at the first pole piece and at the second pole piece; and
   at least one voltage supply, arranged to apply a potential difference between the second pole piece and the sample mounted at the sample position to generate an electric field;
   the generated magnetic field and generated electric field for focusing a beam of charged particles passing through the central apertures of the first and the second pole piece.
2. The charged particle lens of clause 1, wherein the magnetic field is an immersion magnetic field.
3. The charged particle lens of clause 1 or clause 2, wherein the first pole piece and/or the second pole piece is formed of a material that is ferromagnetic or ferrimagnetic and that is electrically conductive.
4. The charged particle lens of any preceding clause, wherein the second pole piece is arranged to be spaced apart from the first pole piece by a gap in the direction of the central axis.
5. The charged particle lens of clause 4, wherein the first and the second pole piece are arranged such that a width of the gap in the direction of the central axis is minimised whilst maintaining electrical insulation between the first and the second pole piece.
6. The charged particle lens of clause 4 or clause 5, wherein the first and the second pole piece are arranged such that an overlap of a primary peak in the magnetic field having a maximum that is the global maximum in the magnetic field with a secondary peak in the magnetic field caused by the gap is maximised.
7. The charged particle lens of any one of clauses 4 to 6, wherein at least a tip portion of the second pole piece is arranged to extend closer to the sample position in the direction of the central axis than any portion of the first pole piece.
8. The charged particle lens of clause 7, wherein the tip portion has a non-zero depth, the depth being a distance between a surface of the first pole piece closest to the sample position and a surface of the second pole piece closest to the sample position, and wherein the second pole piece is configured to minimise the non-zero depth of the tip portion.
9. The charged particle lens of any preceding clause, further comprising an insulating element arranged between the first pole piece and the second pole piece, for electrically insulating the first pole piece from the second pole piece.
10. The charged particle lens of any preceding clause, wherein the charged particle lens is for use within a scanning electron microscope, SEM.
11. A scanning electron microscope, SEM, comprising the charged particle lens of any preceding clause.
12. The SEM of clause 11, further comprising:
   a booster tube extending at least partially through the central aperture of the first pole piece in the direction of the central axis;
   one or more charged particle detectors arranged in the booster tube for receiving charged particles emitted or reflected from the sample.
13. A method of focusing a beam of charged particles towards a sample mounted at a sample position, comprising:
   providing a charged particle lens, comprising:
      a first pole piece, having a central aperture;
      a second pole piece, being electrically insulated from the first pole piece and having a central aperture, wherein the second pole piece is arranged to be aligned with the first pole piece such that a central axis of the charged particle lens extends through the central aperture of the first pole piece and the second pole piece, the central apertures of the first pole piece and the second pole piece for passing the beam of charged particles towards the sample;
      a lens coil arranged to generate a magnetic field at the first pole piece and at the second pole piece; and
      at least one voltage supply, arranged to apply a potential difference between the second pole piece and the sample mounted at the sample position to generate an electric field;
   wherein the method further comprises:
   generating the magnetic field and the electric field whilst passing the beam of charged particles through the central aperture of the first pole piece and the second pole piece towards the sample, the generated magnetic field and generated electric field for focusing the beam of charged particles towards the sample.
14. The method of clause 13, wherein the first pole piece and/or the second pole piece are formed of a material that is ferromagnetic or ferrimagnetic and that is electrically conductive.

In a first described example there is a charged particle lens for focusing a beam of charged particles towards a sample mounted at a sample position, the charged particle lens comprising:
a first pole piece, having a central aperture;
a second pole piece, being electrically insulated from the first pole piece and having a central aperture, wherein the second pole piece is arranged to be aligned with the first pole piece such that a central axis of the charged particle lens extends through the central aperture of the first pole piece and the second pole piece, the central apertures of the first pole piece and the second pole piece for passing the beam of charged particles towards the sample;
a lens coil arranged to generate a magnetic field at the first pole piece and at the second pole piece; and
at least one voltage supply, arranged to apply a potential difference between the second pole piece and the sample mounted at the sample position to generate an electric field;
the generated magnetic field and generated electric field for focusing a beam of charged particles passing through the central apertures of the first and the second pole piece.

The charged particle lens (or compound electrostatic magnetic immersion lens) may be for use in an SEM, and be arranged as the final element of a booster tube of the SEM. The charged particle lens may be used to focus (or magnify or demagnify) a beam of charged particles on to a surface of a sample arranged at a sample position (or sample plane, or sample mount, or sample table). Primarily, the charged particle lens is for use with electrons, although it will be understood that it could be used to direct other ions.

The first and second pole pieces are elements for directing lines of magnetic field. In particular, the first and second pole piece direct a magnetic field, generated by the lens coil, to a have a maximum magnitude of the field close to the sample position (or specifically close to a sample at the sample position). In this way, the first and second pole piece provide an immersion magnetic field, in which the sample is immersed when the charged particle lens is in use.

The first and second pole pieces each have a central aperture (or central bore) therethrough. The central apertures (or bores) of the first and second pole piece are aligned, such that the central axis can pass directly through the apertures of both pole pieces. The alignment is such that a charged particle beam can pass through the central apertures of the first and second pole piece directly, without deflection or redirection. In use, the charged particle beam passes substantially along the central axis. The sample position (and in use, the sample) is aligned with the central axis, such that a charged particle beam passing through central aperture of the first and the second pole piece is incident on the surface of the sample at the sample position.

The first and second pole piece are electrically insulated from each other. This allows a voltage to be applied to either the first or the second pole piece, such that a potential difference is generated between the two pole pieces. In particular, one or more voltage supply is arranged to apply a potential difference between the second pole piece and the sample position or holder (and a sample thereon). This may be by application of a voltage to the second pole piece by a first voltage supply and/or connecting the first pole piece and/or sample position to ground or to a second or further voltage supply. As the second pole piece is electrically isolated from the first pole piece and from the sample position, the second pole piece may be held at a higher voltage than both of the first pole piece and the sample position (and sample). By providing a potential difference in this way, the electrically isolated second pole piece held at a higher voltage to its adjacent elements creates an electrostatic field between it and the sample position (and the first pole piece).

The electrostatic field generated by application of voltage to the isolated second pole piece, and the magnetic field generated by the lens coil and directed by the first and second pole piece, cause a focusing of a charged particle beam passed through the central apertures of the first and second pole piece (i.e. along the central axis) and towards the sample. The electrostatic field can be considered to provide an electrostatic lens, and the magnetic field can be considered to provide a magnetic lens. Together the electrostatic and magnetic field provide an electromagnetic field providing the focusing effect. In this case, focusing of the charged particle beam may comprise magnifying or demagnifying the beam, (in other words, changing the beam width at the focal plane). The second pole piece is decisive for the creation of electrostatic and magnetic rotationally symmetric fields responsible for focusing of charged particles. Unification of the component of the charged particle lens which generates the electrostatic and magnetic fields provides advantages, as described elsewhere in the disclosure.

As discussed above, the magnetic field generated is an immersion magnetic field. As such, any sample placed or mounted at the sample position will be immersed in the magnetic field. The immersion magnetic field has a maximum magnitude (being the global maximum of the magnetic field) close to the sample position. The global maximum of the peak may be in the sample chamber, downstream of the second polepiece. Provision of an immersion magnetic field has been shown to reduce aberrations when used within an SEM booster tube.

The second pole piece is formed of a material that is ferromagnetic or ferrimagnetic and that is electrically conductive. The first pole piece is also formed of a material that is ferromagnetic or ferrimagnetic and that is electrically conductive. This allows the use of the pole pieces to direct the generated magnetic field, and also to support the application of a potential difference between the second pole piece and other adjacent elements (such as the first pole piece and the sample). A ferromagnetic material has an observable magnetic permeability, and typically can form a permanent magnetic. A ferrimagnetic material is a material that has populations of atoms with opposing magnetic moments but of unequal magnitude, so a spontaneous magnetization remains. Examples of suitable ferromagnetic and electrically conductive materials for formation of the first and second pole piece include but are not limited to soft ferromagnetic materials such as pure iron, very low carbon steel, nickel-based alloys (known usually as permalloy) or cobalt-based alloys (known usually as permendur or hiperco). The first and second pole piece may be made of a different type of ferromagnetic (or ferrimagnetic) and electrically conductive material.

Preferably, the second pole piece is arranged to be spaced apart from the first pole piece by a gap in the direction of the central axis. In other words, a portion (specifically, a tip portion) of the second pole piece extends closer to the sample in the direction of the central axis than the first pole piece. In some cases, the second pole piece is arranged so that a first end portion is concentric with the first pole piece, and a second end portion extends away from the first pole piece and towards the sample position. The first pole piece may be substantially frustoconical, with the second pole piece providing a tip for the cone shape.

The second pole piece is electrically isolated from the first pole piece. This may be by way of the second pole piece being physically separated from, displaced from, or spaced apart from the first pole piece. The separation or gap between the first and second pole piece ensures electrical isolation. However, a gap or separation between the first and second pole piece typically causes a local maximum in the generated magnetic field, aligned with the gap in the direction of the central axis. This is due to a discontinuity in the magnetic circuit. This local maximum in the generated magnetic field has the effect of a parasitic magnetic lens. Beneficially, the gap or separation between the first and second pole piece may be situated as close as possible to the sample position in the direction of the central axis, in order to move the local maximum in the generated magnetic field towards the sample position. Ideally, the local maximum in the generated magnetic field will coincide with, or overlap as much as possible with, the global peak or global maximum magnitude in the magnetic field located close to the sample position and which provides the magnetic immersion field discussed above.

In other words, the first and the second pole piece may be arranged such that an overlap is maximised of a primary peak in the magnetic field having a maximum that is the global maximum in the magnetic field with a secondary peak in the magnetic field caused by the gap. The secondary peak has a maximum less, and typically much less, than the global maximum. In particular, the first and the second pole piece are arranged in such a way as to avoid an excessively large secondary peak in the magnetic field as a result of the presence and position of the gap.

In order to move any peak having a local maximum in the magnetic field to overlap as much as possible with the peak associated with the immersion field, the length of extension of the second pole piece in the direction of the central axis from the surface of the first pole piece closest to the sample position may be minimised as much as possible whilst still generating the electric field. Considered another way, at least a tip portion of the second pole piece may be arranged to extend closer to the sample position in the direction of the central axis than any portion of the first pole piece. The tip portion may then have a non-zero depth, the depth being a distance between a surface of the first pole piece closest to the sample position and a surface of the second pole piece closest to the sample position, wherein the second pole piece may be configured to minimise the non-zero depth of the tip portion. In other words, at least a portion of the second pole piece (the “tip portion”) protrudes from the first pole piece in the direction of the sample position, the depth of the tip portion is finite and non-zero but minimised as much as possible. In this way, the gap between the first and second pole piece is provided as close as possible to the tip of the charged particle lens, closest to a sample mounted at the sample position.

Additionally or alternatively, the first and the second pole piece may be arranged such that a width of the gap (or magnitude of the separation) between the first and second pole piece in the direction of the central axis is minimised whilst maintaining electrical insulation between the first and the second pole piece. Minimising the magnitude of any gap or separation minimises the width of any peak having the described local maximum in the magnetic field.

In one example, the distance in the direction of the central axis between the sample position and the centre of the gap may be less than four times the distance in the direction of the central axis between the sample position and a surface of the second pole piece closest to the sample position. In another example, the distance in the direction of the central axis between the sample position and the centre of the gap may be less than twice the distance in the direction of the central axis between the sample position and a surface of the second pole piece closest to the sample position.

Preferably, the charged particle lens further comprises an insulating element arranged between the first pole piece and the second pole piece, for electrically insulating the first pole piece from the second pole piece. The insulating element may be a spacer or washer made from an electrically insulating material. The insulating element may be an electrically insulating element. Examples of materials which may be comprised in or used for forming the insulating element include any non-conductive (i.e. insulating) material that a) can be machined to high precision, b) has a relative permittivity that is as close as possible to 1, and c) that is compatible for use in a high vacuum. Possible materials for forming the insulating material include machinable glass-ceramic (such as Macor®), polyether ether ketone (PEEK), alumina, or aluminium nitride.

The insulating element may fill the gap or the separation between the first and the second pole piece. The insulating element may provide mechanical support to hold the second pole piece with respect to the first pole piece. The insulating element may have a central aperture, with the insulating element being arranged between the first pole piece and the second pole piece such that the central axis of the charged particle lens extends through the central aperture of the first pole piece, the insulating element and the second pole piece. In other words, at least a portion of the second pole piece may be arranged between the insulating element and the sample in the direction of the central axis.

In an example, the insulating element may comprise an open-ended cylindrical portion having a central bore extending therethrough in the direction of the central axis, and further comprise wings extending outwards from an end of the open-ended cylindrical portion. In other words, the outermost surface of the insulating element may be frustoconical, having a cylindrical portion arranged within, the cylinder having a bore or aperture therethrough. This may give the insulating element the appearance of an open-ended, barbed cylinder. The surfaces of the first and second pole piece adjacent to the insulating element may be configured to conform to the shape of the insulating element, so that a surface of the first pole piece is arranged to sit within the valley of the ‘v’ portion between the barb and the cylinder. The described shape of the insulating element may increase a breakdown voltage of the electrical isolation between the first and second pole piece, by increasing the surface area of the insulating element arranged between the first and the second pole piece.

The charged particle lens may be for use within a scanning electron microscope, SEM.

In a second example, there is a scanning electron microscope, SEM, comprising the charged particle lens as described above. The SEM may further comprise a booster tube extending at least partially through the central aperture of the first and/or second pole piece in the direction of the central axis. The SEM may further comprise one or more charged particle detectors arranged in the booster tube for receiving charged particles emitted or reflected from the sample. In particular, a first charged particle detector may be a backscattered electron detector, arranged within the central aperture of the first pole piece. A second charged particle detector may be a secondary electron detector, aligned with the central axis such that the first pole piece is arranged between the second pole piece and the secondary electron detector. The charged particle lens may be of particular benefit for use in an SEM, because the implementation of a single element (the second pole piece, being a combined magnetic and electrostatic lens) for directing and focusing the electrostatic and magnetic fields reduces aberration in images at the SEM than compared to prior art designs with separate electrostatic and magnetic lens.

In a third example, there is a method of focusing a beam of charged particles towards a sample mounted at a sample position, comprising:
providing a charged particle lens, comprising:
   a first pole piece, having a central aperture;
   a second pole piece, being electrically insulated from the first pole piece and having a central aperture, wherein the second pole piece is arranged to be aligned with the first pole piece such that a central axis of the charged particle lens extends through the central aperture of the first pole piece and the second pole piece, the central apertures of the first pole piece and the second pole piece for passing the beam of charged particles towards the sample;
   a lens coil arranged to generate a magnetic field at the first pole piece and at the second pole piece; and
   at least one voltage supply, arranged to apply a potential difference between the second pole piece and the sample mounted at the sample position to generate an electric field;
wherein the method further comprises:
generating the magnetic field and the electric field whilst passing the beam of charged particles through the central aperture of the first pole piece and the second pole piece towards the sample, the generated magnetic field and generated electric field for focusing the beam of charged particles towards the sample.

Preferably the first pole piece and/or the second pole piece is formed of a ferromagnetic or ferrimagnetic and electrically conductive material.

Preferably, the second pole piece is spaced apart from the first pole piece by a gap in the direction of the central axis. The first and the second pole piece may be arranged such that an overlap of a primary peak in the magnetic field having a maximum that is the global maximum in the magnetic field with a secondary peak in the magnetic field caused by the gap is maximised. At least a tip portion of the second pole piece may be arranged to extend closer to the sample position in the direction of the central axis than any portion of the first pole piece. The tip portion may have a non-zero depth, the depth being a distance between a surface of the first pole piece closest to the sample position and a surface of the second pole piece closest to the sample position, and wherein the second pole piece may be configured to minimise the non-zero depth of the tip portion. Additionally or alternatively, the magnitude of the gap (in the direction of the central axis) may be minimised whilst maintaining electrical insulation between the first and the second pole piece.

The method may further comprise providing an insulating element arranged between the first pole piece and the second pole piece, for electrically insulating the first pole piece from the second pole piece. The insulating element may fill the gap between the first and the second pole piece.

In a fourth example, there may be a method of obtaining images of a sample by use of the described charged particle lens in a scanning electron microscope (SEM).

1. A charged particle lens for focusing a beam of charged particles towards a sample mounted at a sample position, the charged particle lens comprising:
a first pole piece, having a central aperture;
a second pole piece, being electrically insulated from the first pole piece and having a central aperture, wherein the second pole piece is arranged to be aligned with the first pole piece such that a central axis of the charged particle lens extends through the central aperture of the first pole piece and the second pole piece, the central apertures of the first pole piece and the second pole piece for passing the beam of charged particles towards the sample;
a lens coil arranged to generate a magnetic field at the first pole piece and at the second pole piece; and
at least one voltage supply, arranged to apply a potential difference between the second pole piece and the sample mounted at the sample position to generate an electric field;
the generated magnetic field and generated electric field for focusing a beam of charged particles passing through the central apertures of the first and the second pole piece.

2. The charged particle lens of claim 1, wherein the magnetic field is an immersion magnetic field.

3. The charged particle lens of claim 1, wherein the first pole piece and/or the second pole piece is formed of a material that is ferromagnetic or ferrimagnetic and that is electrically conductive.

4. The charged particle lens of claim 1, wherein the second pole piece is arranged to be spaced apart from the first pole piece by a gap in the direction of the central axis.

5. The charged particle lens of claim 4, wherein the first and the second pole piece are arranged such that a width of the gap in the direction of the central axis is minimised whilst maintaining electrical insulation between the first and the second pole piece.

6. The charged particle lens of claim 4, wherein the first and the second pole piece are arranged such that an overlap of a primary peak in the magnetic field having a maximum that is the global maximum in the magnetic field with a secondary peak in the magnetic field caused by the gap is maximised.

7. The charged particle lens of claim 4, wherein at least a tip portion of the second pole piece is arranged to extend closer to the sample position in the direction of the central axis than any portion of the first pole piece.

8. The charged particle lens of claim 7, wherein the tip portion has a non-zero depth, the depth being a distance between a surface of the first pole piece closest to the sample position and a surface of the second pole piece closest to the sample position, and wherein the second pole piece is configured to minimise the non-zero depth of the tip portion.

9. The charged particle lens of claim 1, further comprising an insulating element arranged between the first pole piece and the second pole piece, for electrically insulating the first pole piece from the second pole piece.

10. The charged particle lens of claim 1, wherein the charged particle lens is for use within a scanning electron microscope, SEM.

11. A scanning electron microscope, SEM, comprising the charged particle lens of claim 1.

12. The SEM of claim 11, further comprising:
a booster tube extending at least partially through the central aperture of the first pole piece in the direction of the central axis;
one or more charged particle detectors arranged in the booster tube for receiving charged particles emitted or reflected from the sample.

13. A method of focusing a beam of charged particles towards a sample mounted at a sample position, comprising:
providing a charged particle lens, comprising:
a first pole piece, having a central aperture;
a second pole piece, being electrically insulated from the first pole piece and having a central aperture, wherein the second pole piece is arranged to be aligned with the first pole piece such that a central axis of the charged particle lens extends through the central aperture of the first pole piece and the second pole piece, the central apertures of the first pole piece and the second pole piece for passing the beam of charged particles towards the sample;
a lens coil arranged to generate a magnetic field at the first pole piece and at the second pole piece; and
at least one voltage supply, arranged to apply a potential difference between the second pole piece and the sample mounted at the sample position to generate an electric field;
wherein the method further comprises:
generating the magnetic field and the electric field whilst passing the beam of charged particles through the central aperture of the first pole piece and the second pole piece towards the sample, the generated magnetic field and generated electric field for focusing the beam of charged particles towards the sample.

14. The method of claim 13, wherein the first pole piece and/or the second pole piece are formed of a material that is ferromagnetic or ferrimagnetic and that is electrically conductive.
